(19) United States
(12) Patent Application Publication
(10) Pub. No.: US 2014/0370624 A1
(43) Pub. Date: Dec. 18, 2014

(54) WAFER ALIGNMENT AND BONDING TOOL FOR 3D INTEGRATION

(71) Applicant: International Business Machines Corporation, Armonk, NY (US)

(72) Inventors: Mukta G. Farooq, Hopewell Junction, NY (US); Spyridon Skordas, Hopewell Junction, NY (US)

(21) Appl. No.: 13/920,138

(22) Filed: Jun. 18, 2013

(51) Int. Cl. H01L 21/68; G01B 11/27

(52) U.S. Cl. CPC H01L 21/681; G01B 11/272
USPC 438/5; 156/379

(57) ABSTRACT

A bonding apparatus for 3D integration may include a plurality of infrared microscopes that emit and receive infrared light for imaging, a first bonding chuck that holds a first semiconductor structure, and a second bonding chuck that holds a second semiconductor structure, whereby the second bonding chuck has a plurality of openings that are transparent to the received infrared light. A force pin is coupled to the first bonding chuck for applying a predetermined force to the first semiconductor structure for bonding to the second semiconductor structure. A temperature controller is coupled to the second bonding chuck, whereby the temperature controller applies a predetermined temperature to the second semiconductor structure, such that, prior to the bonding, the first and the second semiconductor structure are de-aligned with respect to each other using the plurality of infrared microscopes and the plurality of openings. The de-alignment is based on the predetermined force and the application of the predetermined temperature.

### BACKGROUND

a. Field of the Invention

The present invention generally relates to 3-dimensional (3D) integration of semiconductor structures, and more particularly, to the alignment of semiconductor structures (e.g., wafers) during such 3D integration processes.

b. Background of Invention

In wafer-scale 3-dimensional (3D) integration, achieving good alignment may be a key requirement. In traditional bonding methods, the alignment may typically be done indirectly. Accordingly, for example, a first wafer may be placed on an upper bonding chuck. A set of microscopes (e.g., two microscopes) then align to the desired alignment marks of the first wafer that is placed on the upper bonding chuck. Following this alignment process, the position of the first wafer is recorded and stored.

The same procedure is then repeated for the second wafer using a different set of microscopes (e.g., two other microscopes), whereby the different set of microscopes (e.g., two microscopes) align to the desired alignment marks of the second wafer that is placed on the lower bonding chuck. Following this alignment, the position of the second wafer is also recorded and stored.

Subsequently, based on the stored positions, the wafers can be bonded through a variety of methods, such as, for example, direct fusion bonding, thermal compression bonding, etc. However, such an alignment method may be limited by the performance of bond chuck position calibrations, microscope position calibrations, accuracy of the mechanical systems used to drive precision positioning, and/or other factors. Thus, some misalignment between the wafers becomes probable.

In order to, therefore, mitigate the effects of such wafer misalignment, it may be necessary to create larger conductive landing pads on the wafers for facilitating electrical connectivity between the stacked wafers during the process of creating through silicon vias (TSV), which may impose a real-estate penalty during chip design. Particularly, in a 3D integration that includes a bonded upper and lower wafer structure, if a TSV is used to connect conductive elements of the upper wafer to a conductive landing pad of the lower wafer, a bonding misalignment may cause the TSV, in an extreme case, to miss the lower wafer landing pad, resulting in an undesirable open circuit.

It may, therefore, be desirable, among other things, to further enhance wafer alignment in 3D wafer integration.

### BRIEF SUMMARY

According to at least one exemplary embodiment, a bonding apparatus may include a plurality of infrared microscopes that receive and emit infrared light for imaging, a first bonding chuck that holds a first semiconductor structure and a second bonding chuck that holds a second semiconductor structure, whereby the second bonding chuck has a plurality of openings that are transparent to the received infrared light. A force pin is coupled to the first bonding chuck such that the force pin applies a predetermined force to the first semiconductor structure for bonding to the second semiconductor structure. A temperature controller is coupled to the second bonding chuck, whereby the temperature controller applies a predetermined temperature to the second semiconductor structure, such that, prior to the bonding, the first and the second semiconductor structure are de-aligned with respect to each other using the plurality of infrared microscopes and the plurality of openings. The de-aligning is based on the predetermined force and the application of the predetermined temperature.

According to at least one other exemplary embodiment, a method of bonding a first semiconductor structure located within a first bonding chuck to a second semiconductor structure located within a second bonding chuck is provided. The first bonding chuck is positioned relative to the second bonding chuck such that at least a first and a second alignment marker associated with the first semiconductor structure are substantially facing at least a third and a fourth alignment marker associated with the second semiconductor structure. The third alignment marker is de-aligned with respect to the first alignment marker using a first infrared microscope, whereby the first infrared microscope receives infrared light from the first and third alignment marker via an opening in the second bonding chuck. The fourth alignment marker may also be de-aligned with respect to the second alignment marker by a second infrared microscope, such that the second infrared microscope receives infrared light from the second and fourth alignment marker via an other opening in the second bonding chuck. The first and the second semiconductor structure are then bonded by the mechanical compression of the first and the second semiconductor structure together using the first and the second bonding chuck, whereby the de-aligning of the third and the fourth alignment marker is accomplished by applying a temperature to the first chuck.

According to yet another exemplary embodiment, a bonding chuck apparatus may include a first bonding chuck that holds a first semiconductor structure and a second bonding chuck that holds a second semiconductor structure such that the second bonding chuck has a plurality of openings that are transparent to infrared light associated with a plurality of infrared microscopes. The plurality of openings facilitate de-aligning the first and the second semiconductor structures using the plurality of infrared microscopes. A force pin is coupled to the first bonding chuck, whereby the force pin applies a predetermined force to the first semiconductor structure for bonding to the second semiconductor structure. Also included is a temperature controller that is coupled to the second bonding chuck, whereby the temperature controller applies a predetermined temperature to the second semiconductor structure for causing the de-aligning prior to the bonding. Upon bonding of the first semiconductor structure to the second semiconductor structure by the force pin, the first and the second semiconductor structure are realigned with respect to each other based on the application of the predetermined temperature prior to the bonding.

### BRIEF DESCRIPTION OF THE SEVERAL VIEWS OF THE DRAWINGS

FIGS. 1A-1C depict an operational flow diagram corresponding to a bonding process according to an exemplary embodiment;

FIGS. 2A-2B are cross-sectional representations of a bonding chuck apparatus during the bonding process of FIGS. 1A-1C according to one exemplary embodiment; and

FIGS. 3A-3B are cross-sectional representations of a bonding chuck apparatus during the bonding process of FIGS. 1A-1C according to another exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

The following one or more exemplary embodiments describe providing process parameter changes that actively optimize alignment during live wafer bonding processes. Thus, by providing at least one more degree of freedom (e.g., temperature control) in optimizing the alignment between semiconductor structures (e.g., wafers), any misalignment between such stacked semiconductor structures may be further reduced.

As described below, the misalignment between stacked semiconductor structures may be reduced by de-aligning the structures prior to bonding. By de-aligning the structures prior to the bonding process, alignment changes that result from the actual bonding process may be pre-compensated. Moreover, further de-alignment of the structures prior to the bonding processes may be utilized based on any existing misalignment between the semiconductor structures. For example, one semiconductor structure may be distorted related to another semiconductor structure such that prior to bonding, the alignment markers associated with one semiconductor structure do not precisely align with the alignment markers associated with the other semiconductor structure.

Although the following exemplary embodiments are related to stacking semiconductor structures such as semiconductor dies and/or wafers, the method and apparatus described herein may apply to the 3D stacking of any other substrate type, whereby a substrate type may, for example, apply to, without limitation, any medium upon which one or more electrical, mechanical, or electro-mechanical devices and/or connections may be fabricated.

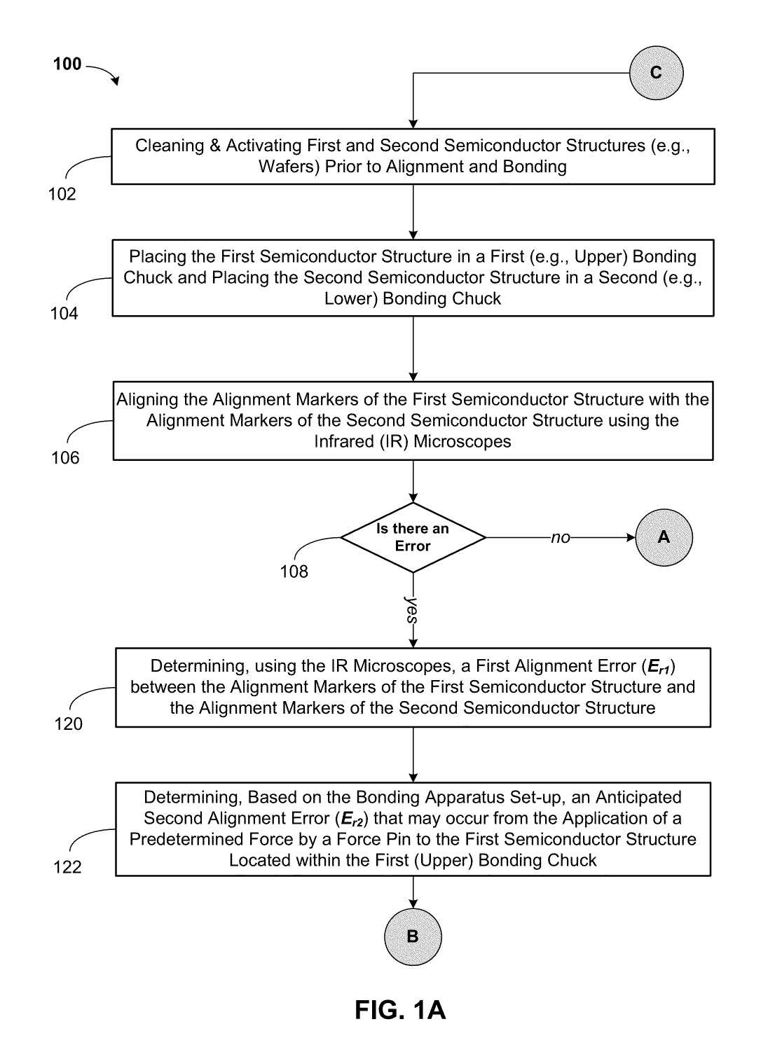

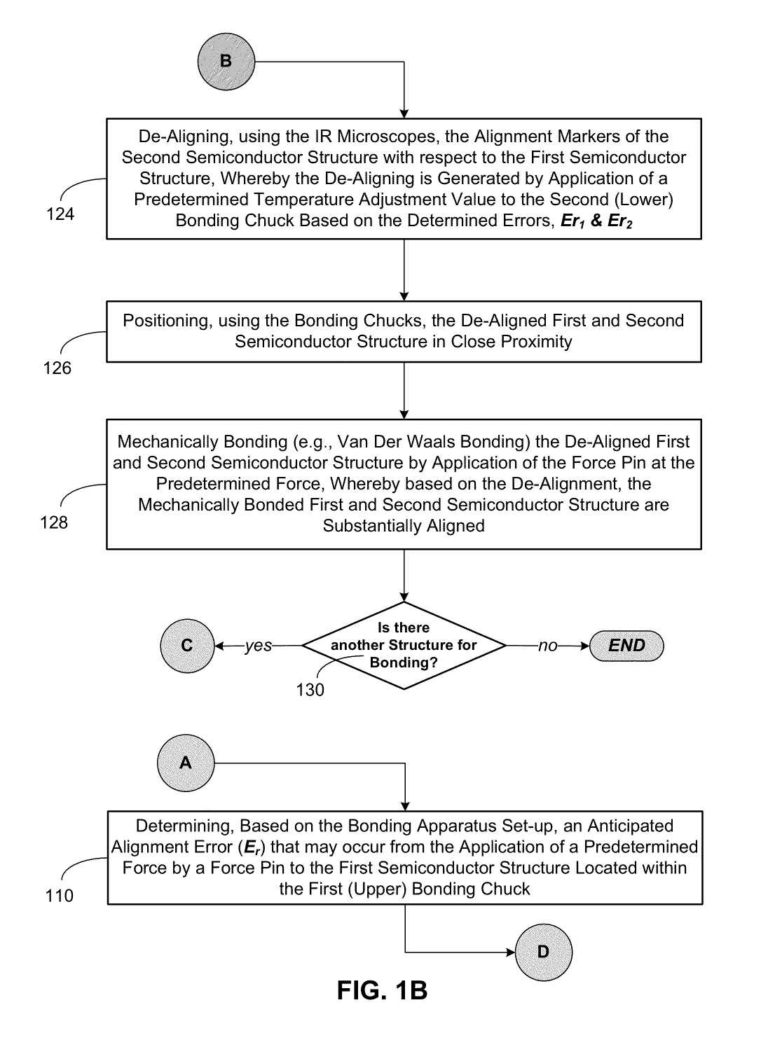

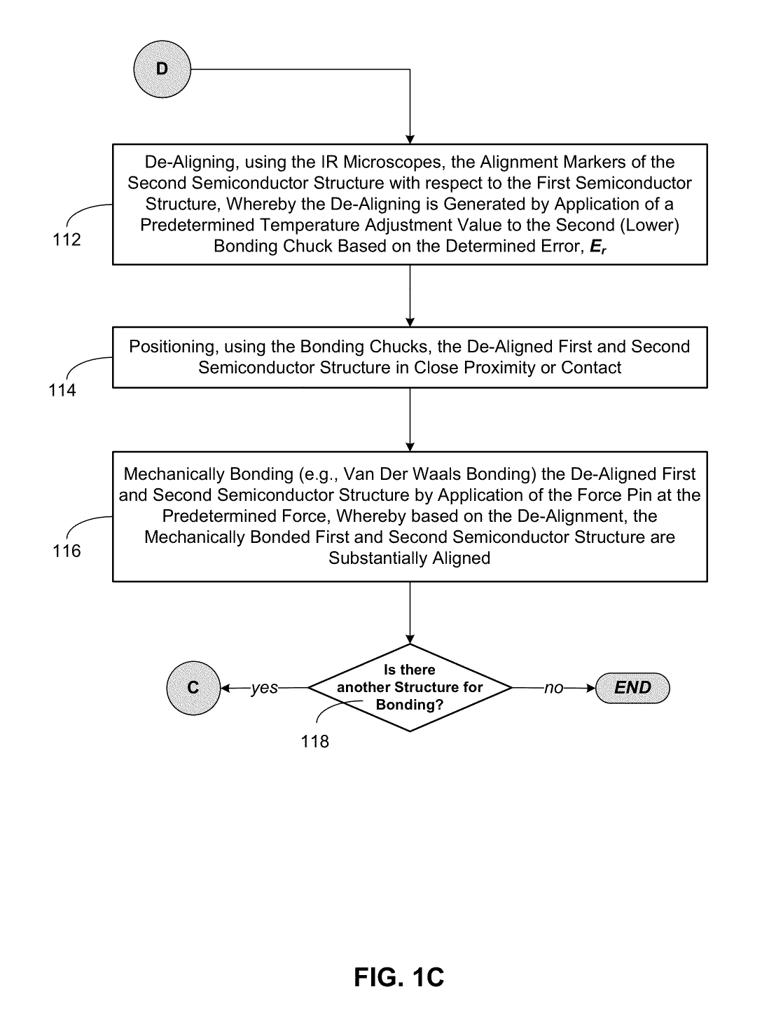

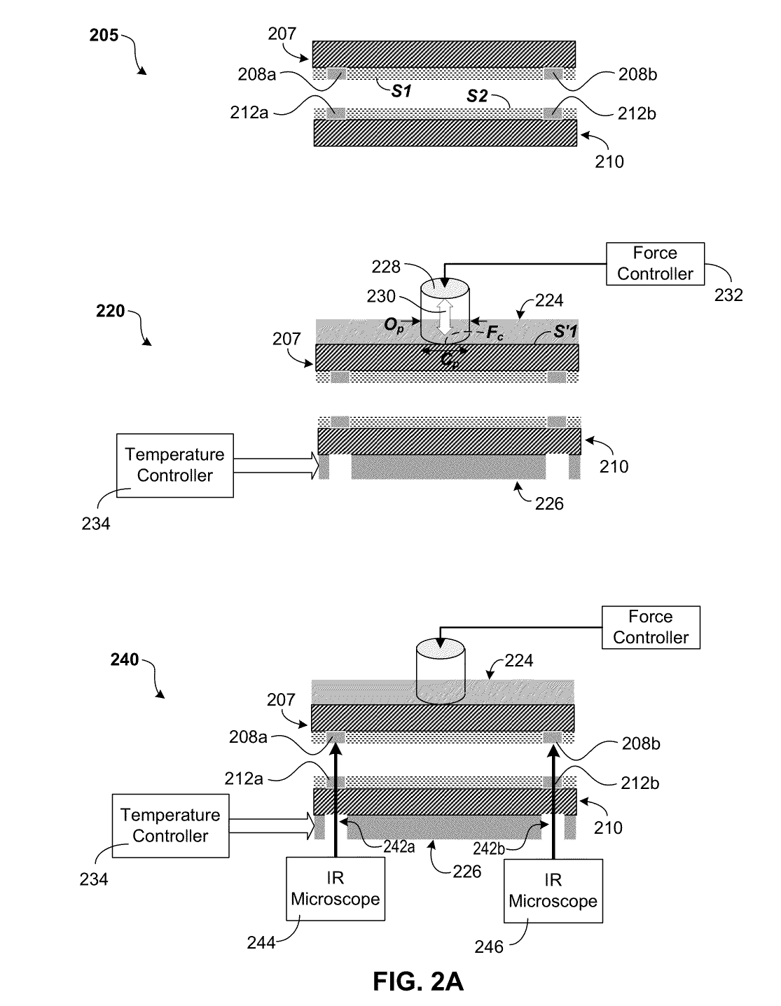

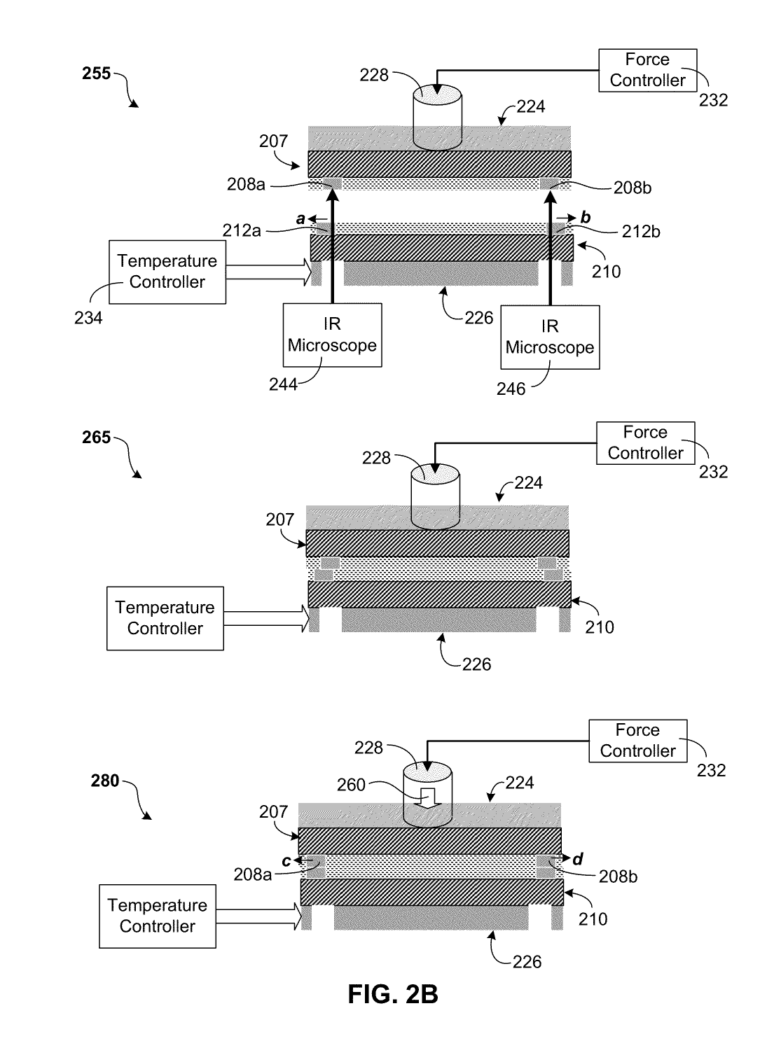

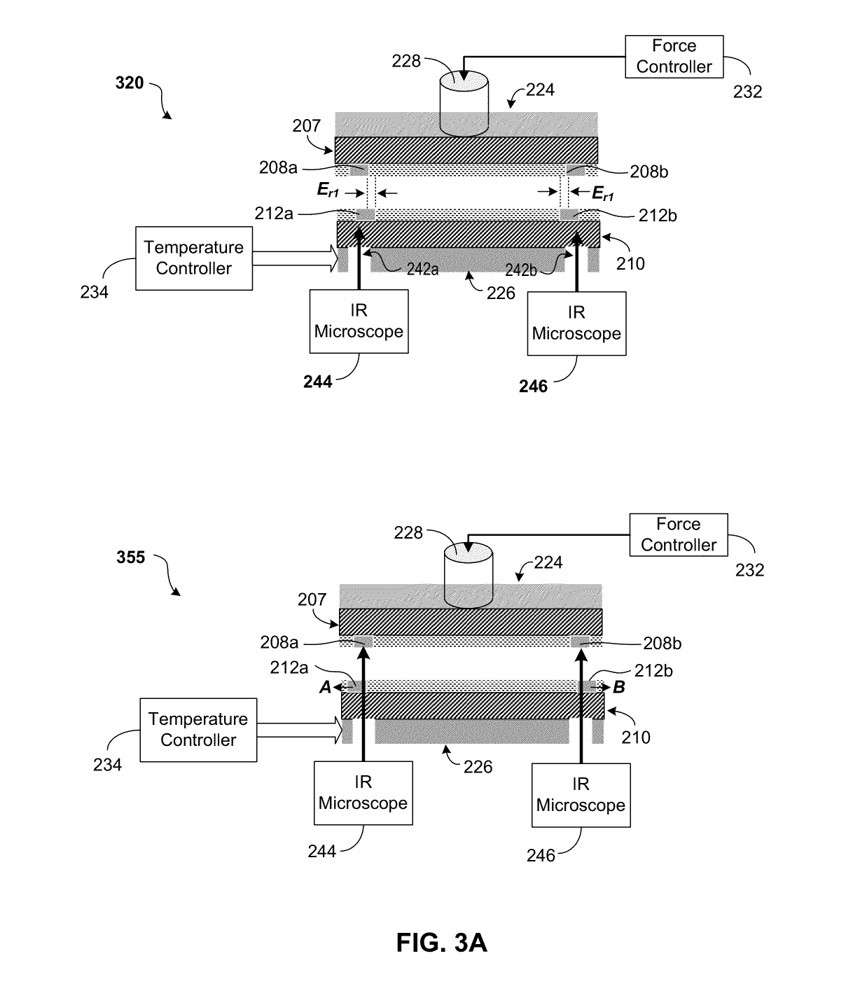

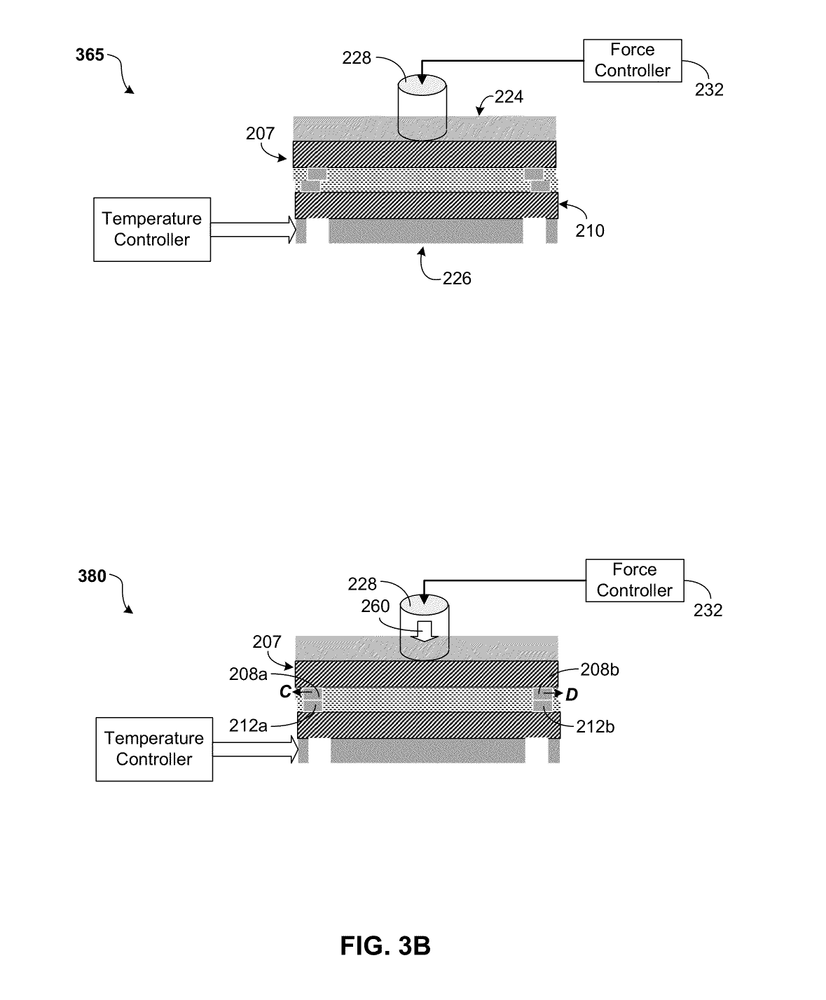

Referring to FIGS. 1A-1C, an operational flow diagram 100 corresponding to a bonding process according to an exemplary embodiment is depicted. The operational flow diagram 100 is described with the aid of FIGS. 2A-2B and 3A-3B, which accordingly depict cross-sectional views associated with embodiments of a bonding apparatus.

At 102, a first semiconductor structure (e.g., a wafer or die) and a second semiconductor structure (e.g., a wafer or die) are cleaned (e.g., HF clean) and activated (e.g., plasma activation) for bonding processes. Referring to FIG. 2A, as indicated by 205, a first (upper) semiconductor structure 207 having alignment markers 208a and 208b is depicted. The surface S1 of semiconductor structure 207 is thus cleaned and activated prior to bonding. As further indicated by 205, a second (lower) semiconductor structure 210 having alignment markers 212a and 212b is also depicted. The surface S2 of semiconductor structure 210 is similarly cleaned and activated prior to bonding to surface S1 of semiconductor structure 207. An initial bonding phase may include a Van Der Waals mechanical bonding, whereby surface S1 of semiconductor structure 207 is mechanically bonded to surface S2 of semiconductor structure 210 via mechanical compression.

At 104, the first and the second semiconductor structures 207, 210 may be place in their respective bonding chucks for facilitating alignment and bonding processes. Referring to FIG. 2A, as indicated by 220, the first (upper) semiconductor structure 207 may be placed within a first (upper) bonding chuck 224 and the second (lower) semiconductor structure 210 may be placed within a second (lower) bonding chuck 226. As depicted in FIG. 2A, a force pin 228 may be coupled to the first (upper) bonding chuck 224, whereby the force pin 228 is adapted to actuate in the direction of arrow 230 within opening Oₚ of the first bonding chuck 224 and, thus, apply a predetermined force to a substantially center portion Cₚ of surface S′1 of semiconductor structure 207. The force pin 228 may be controlled by force controller actuation device 232, which provides the predetermined force having a range of about 0.5 Newtons to about 10 Newtons. The force pin 228 may be substantially cylindrical or piston shaped with a flat facet F_{c} for engaging surface S′1 of semiconductor structure 207.

As further depicted in FIG. 2A, a temperature controller 234 may be coupled to the second (lower) bonding chuck 226, whereby the temperature controller controls the temperature of the second (lower) bonding chuck 226 and, therefore, the temperature of the second semiconductor structure 210. The temperature controller may increase the temperature of the second semiconductor structure 210, via the second (lower) bonding chuck 226, between, for example, about 0 degrees to about 10 degrees (typically 1-2 degrees Celsius) with respect to its ambient temperature. For example, if the temperature of the second semiconductor structure 210 located within the second (lower) bonding chuck 226 is at an ambient temperature of 20 degrees Celsius based on the temperature of the room, the temperature controller may adjust the temperature of the second semiconductor structure 210 to any predetermined temperature value between 20 degrees and 30 degrees Celsius. Based on the material (e.g., Silicon) of the second semiconductor structure 210, an increase in temperature provides a physical expansion of the geometric size of the second semiconductor structure 210. For example, silicon may undergo approximately 2.0 parts-per-million per degree Celsius of distortion. Thus, for a 300 mm wafer, for each degree of temperature increase, the wafer will expand by about 0.6 μm. Over the 0-10 degree temperature adjustment range, the wafer will expand between about 0 μm to about 6.0 μm.

Similarly, the temperature controller may decrease the temperature of the second semiconductor structure 210, via the second (lower) bonding chuck 226, between, for example, about 0 degrees to about 10 degrees (typically 1-2 degrees Celsius) with respect to its ambient temperature. For example, if the temperature of the second semiconductor structure 210 located within the second (lower) bonding chuck 226 is at an ambient temperature of 20 degrees Celsius based on the temperature of the room, the temperature controller may adjust the temperature of the second semiconductor structure 210 to any predetermined temperature value between 20 degrees and 10 degrees Celsius. Based on the material of the second semiconductor structure 210 being Silicon, a decrease in temperature provides a physical contraction of the geometric size of the second semiconductor structure 210. For example, as previously indicated, silicon may undergo approximately 2.0 parts-per-million per degree Celsius of distortion. Thus, for a 300 mm wafer, for each degree of temperature decrease, the wafer will conversely contract by about 0.6 μm. Over the 0-10 degree temperature adjustment range, the wafer will contract between about 0 μm to about 6.0 μm.

Accordingly, the temperature controller 234 may control the temperature of the second bonding chuck 226 and, therefore, the second semiconductor structure 210, which in turn facilitates the controlled geometric expansion or contraction of the second semiconductor structure 210 for live alignment purposes.

At 106, the alignment markers of the first and the second semiconductor structures 207, 210 may be aligned using a pair of infrared (IR) microscopes. Referring to FIG. 2A, as indicated by 240, the second (lower) bonding chuck 226 may include IR windows 242a and 242b. In some implementations, the IR windows 242a, 242b may include openings. Alternatively, in other implementations, the IR windows 242a, 242b may include any material that allows the transmission of IR light and, therefore, facilitates the operation of IR microscopes 244 and 246. As depicted, IR microscope 244 images alignment markers 212a and 208a for alignment purposes via IR window 242a, while IR microscope 246 similarly images alignment markers 212b and 208b for alignment purposes via IR window 242b.

Based on the alignment process (106) using microscopes 244 and 246 (FIG. 2A: at 240), at 108 it may be determined whether any alignment errors exist between the alignment markers of the semiconductor structures. Referring to FIG. 2A, as indicated by 240, alignment markers 212a and 208a, and alignment markers 212b and 208b, may or may not be substantially aligned based on any distortion exhibited by one semiconductor structure relative to the other. For example, by aligning alignment markers 212a and 208a using the IR microscope 244, the other alignment markers 212b, 208b may not substantially align. In such a scenario, if for example, an alignment error of 5 μm is determined between alignment markers 212b and 208b, the alignment error (i.e., 5 μm) is equally redistributed between the first and the second semiconductor structure 207, 210. Accordingly, the position of alignment markers 208a and 208b may be re-aligned relative to alignment markers 212a and 212b, such that an alignment error of 2.5 μm (i.e., 5 μm/2) exists between alignment markers 212a and 208a, and an alignment error of 2.5 μm (i.e., 5 μm/2) exists between alignment markers 212b and 208b.

However, if at 108 it is determined that no error (or a negligible error) exists between alignment markers 212a and 208a, and alignment markers 212b and 208b (FIG. 2A: at 240), at 110 (FIG. 1B), an anticipated alignment error Eᵣ may be determined based on the application of a predetermined force by the force pin to the upper first semiconductor structure. For example, referring to FIG. 2B, as indicated by 255, it may be determined that based on the set-up of the bonding system, a force of 5 Newtons is required to be applied by the force pin 228 to upper semiconductor structure 207 under the control of force controller 232. The predetermined force of 5 Newtons may be established based on, for example, the thickness and material, among other things, of the semiconductor structure 207. Also, based on calibration processes or existing technical data, it may be determined that a 5 Newton force applied to the semiconductor structure 207 creates 2.0 parts-per-million (ppm) of distortion. Thus, for a 300 mm semiconductor structure, semiconductor structure 207 may expand by about 0.6 μm under the 5 Newton force applied by the force pin 228.

At 112 (FIG. 1C), based on the determined alignment error Eᵣ (i.e., 0.6 μm) anticipated by the application of the force pin 228 (FIG. 2B: at 255), the alignment markers 212a, 212b corresponding to the lower second semiconductor structure 210 are de-aligned with respect to the alignment markers 208a, 208b corresponding to the upper first semiconductor structure 207. By de-aligning the markers, any distortion experienced via the application of the force pin 228 during the bonding phase may be compensated. Thus, based on the above example, for a predicted 0.6 μm expansion caused by the application of the force pin 228 to upper semiconductor structure 207, the alignment markers 212a, 212b corresponding to the lower second semiconductor structure 210 are de-aligned by 0.6 μm with respect to the alignment markers 208a, 208b corresponding to the upper first semiconductor structure 207. This is indicated by directional arrows a and b, which are indicative of the direction of de-alignment.

Accordingly, using IR microscopes 244 and 246, the alignment markers 212a, 212b corresponding to the lower second semiconductor structure 210 are de-aligned by applying a predetermined temperature to the second bonding chuck 226 via temperature controller 234. As previously described, for a 300 mm wafer, for each degree of temperature increase, the wafer will expand by about 0.6 μm (i.e., 2.0 ppm/degree Celsius or Silicon). Thus, by applying a 1 degree Celsius increase in the temperature of the lower second semiconductor structure 210 via bonding chuck 226, each of the alignment markers will move in the direction of arrows a and b by 0.3 μm, which provides a total de-alignment between the alignment markers 212a, 212b of 0.6 μm. Following the de-aligning (112), at 114 (FIG. 1C), as indicated at 265 (FIG. 2B), the bonding chucks 224, 226 are brought into close proximity (but not in contact yet) prior to bonding.

At 116 (FIG. 1C), as indicated at 280 (FIG. 2B), the de-aligned first and second semiconductor structures 207, 210 that may be in contact or close proximity are coupled under the actuation of the force pin 228 in the direction of arrow 260. More specifically, under the applied predetermined force exerted by the force pin 228, the upper first semiconductor structures 207 is mechanically bonded to the second semiconductor structures 210 by means of Van Der Waals bonding.

Under the force of the force pin 228, as previously described, the upper first semiconductor structures 207 may undergo distortion, whereby the alignment markers 208a, 208b of the upper first semiconductor structures 207 expand in the direction of arrows c and d. For example, for a 5 Newton force applied to semiconductor structure 207, the semiconductor structure 207 may undergo 2.0 ppm of distortion. Thus, the upper first semiconductor structure 207 and thus its corresponding alignment marker may expand by about 0.6 μm under the 5 Newton force applied by force pin 228. Each of the alignment markers will, therefore, move in the direction of arrows c and d by 0.3 μm, which provides a total alignment shift between the alignment markers 208a, 208b of 0.6 μm. As depicted, the alignment shift between the alignment markers 208a, 208b of the upper semiconductor structure 207 caused by the applied predetermined bonding force correspond in magnitude to the de-alignment of the markers 208a, 208b of the lower semiconductor structure 210 caused by the applied predetermined temperature. Therefore, as depicted by 280, the alignment markers 208a, 208b respectively align with alignment markers 212a and 212b following the mechanical bonding process.

At 118 (FIG. 1C), it may then be determined if the current bonded semiconductor structure is going to be bonded to another semiconductor structure. If not, processing ends. If so, the process returns to 102 of FIG. 1A.

Referring back to FIG. 1A, in an alternative scenario, at 108 it may be determined, using the IR microscope pair, that an existing alignment error does exist between the alignment markers. If so, at 120 an alignment error Eᵣ₁ between the alignment markers may be determined using the IR microscope pair. For example, as referred to in FIG. 3A and indicated by 320, the alignment markers of the first and the second semiconductor structures 207, 210 may be aligned using the IR microscope pair 244, 246 in order to determined the magnitude of the alignment error Eᵣ₁. As depicted, IR microscope 244 images alignment markers 212a and 208a for alignment purposes via IR window 242a, while IR microscope 246 similarly images alignment markers 212b and 208b for alignment purposes via IR window 242b. For example, by aligning alignment markers 212a and 208a using the IR microscope 244, the other alignment markers 212b, 208b may not substantially align. In such a scenario, if for example, an alignment error of 5 μm is determined between alignment markers 212b and 208b, the alignment error (i.e., 5 μm) is equally redistributed between the first and the second semiconductor structure 207, 210. Accordingly, the position of alignment markers 208a and 208b may be re-aligned relative to alignment markers 212a and 212b, such that an alignment error of Eᵣ₁=2.5 μm (i.e., 5 μm/2) exists between alignment markers 212a and 208a, and an alignment error of Eᵣ₁=2.5 μm (i.e., 5 μm/2) exists between alignment markers 212b and 208b.

Moreover, at 122 (FIG. 1A), an anticipated or predicted alignment error Eᵣ₂ may also be determined based on the application of a predetermined force by the force pin 228 to the upper first semiconductor structure 207. For example, it may be determined that based on the set-up of the bonding system, a force of 5 Newtons is required to be applied by the force pin 228 to upper semiconductor structure 207 under the control of force controller 232. The predetermined force of 5 Newtons may be established based on, for example, the thickness and material, among other things, of the semiconductor structure 207. Also, based on calibration processes or existing technical data, it may be determined that a 5 Newton force applied to the semiconductor structure 207 creates 2.0 parts-per-million (ppm) of distortion during the mechanical bonding phase. Thus, as previously indicated, for a 300 mm semiconductor structure, semiconductor structure 207 may expand by about 0.6 μm under the force applied by the force pin 228 during bonding.

At 124 (FIG. 1B), based on the determined total alignment error magnitudes Eᵣ₁+Eᵣ₂ (i.e., 0.6 μm+0.6 μm), the alignment markers are de-aligned in order to compensate for the error magnitudes Eᵣ₁+Eᵣ₂ during subsequent bonding processes. For example, referring to 355 of FIG. 3A, the alignment markers 212a, 212b corresponding to the lower second semiconductor structure 210 are de-aligned with respect to the alignment markers 208a, 208b corresponding to the upper first semiconductor structure 207. By de-aligning the markers, any existing alignment errors between the markers (i.e., Eᵣ₁) and any distortion based alignment errors (i.e., Eᵣ₂) experienced via the application of the force pin 228 during the bonding phase may be compensated. Thus, based on the above example, for a total 1.2 μm (0.6 μm+0.6 μm) determined expansion, the alignment markers 212a, 212b corresponding to the lower second semiconductor structure 210 are de-aligned by 1.2 μm with respect to the alignment markers 208a, 208b corresponding to the upper first semiconductor structure 207. This is indicated by directional arrows A and B, which are indicative of the direction of de-alignment.

Accordingly, using IR microscopes 244 and 246, the alignment markers 212a, 212b corresponding to the lower second semiconductor structure 210 are de-aligned by applying a predetermined temperature to the second bonding chuck 226 via temperature controller 234. As previously described, for a 300 mm wafer, for each degree of temperature increase, the wafer will expand by about 0.6 μm (i.e., 2.0 ppm/degree Celsius or Silicon). Thus, by applying a 2 degree Celsius increase in the temperature of the lower second semiconductor structure 210 via bonding chuck 226, each of the alignment markers will move in the direction of arrows A and B by 0.6 μm, which provides a total de-alignment between the alignment markers 212a, 212b of 1.2 μm. Following the de-aligning (124), at 126 (FIG. 1B), as indicated at 365 (FIG. 3B), the bonding chucks 224, 226 are brought into close proximity (but not in contact yet) prior to bonding.

At 128 (FIG. 1B), as indicated at 380 (FIG. 3B), the de-aligned first and second semiconductor structures 207, 210 that may be in contact or close proximity are coupled under the actuation of the force pin 228 in the direction of arrow 260. More specifically, under the applied predetermined force exerted by the force pin 228, the upper first semiconductor structures 207 is mechanically bonded to the second semiconductor structures 210 by means of Van Der Waals bonding. Under the force of the force pin 228, as previously described, the upper first semiconductor structures 207 may undergo distortion, whereby the alignment markers 208a, 208b of the upper first semiconductor structures 207 expand in the direction of arrows C and D.

For example, for a 5 Newton force applied to semiconductor structure 207, the semiconductor structure 207 may undergo 2.0 ppm of distortion. Thus, the upper first semiconductor structure 207 and thus its corresponding alignment markers may expand by about 0.6 μm under the 5 Newton force applied by force pin 228. Each of the alignment markers will, therefore, move in the direction of arrows C and D by 0.3 μm, which provides a total alignment shift between the alignment markers 208a, 208b of 0.6 μm. As depicted, the alignment shift between the alignment markers 208a, 208b of the upper semiconductor structure 207 caused by the applied predetermined bonding force correspond in magnitude to the de-alignment of the markers 208a, 208b of the lower semiconductor structure 210 caused by the applied predetermined temperature. As described above, the temperature compensates for the existing 0.3 μm alignment error between markers 208a and 212a and the 0.3 μm alignment error between markers 208b and 212b. The temperature also compensates for the anticipated 0.3 μm alignment error between markers 208a and 212a and the anticipated 0.3 μm alignment error between markers 208b and 212b caused by the force pin 228 during bonding. Therefore, as depicted by 380, the alignment markers 208a, 208b respectively align with alignment markers 212a and 212b following the mechanical bonding process.

At 130 (FIG. 1B), it may then be determined if the current bonded semiconductor structure is going to be bonded to another semiconductor structure. If not, processing ends. If so, the process returns to 102 of FIG. 1A.

In the above described exemplary embodiment shown in FIG. 3A, and indicated at 320, the alignment markers are misaligned in a manner that required the lower semiconductor structure 210 to be expanded via a controlled predetermined temperature increase. It may be appreciated, however, that in some embodiments (not shown), the alignment markers may be misaligned in an alternative manner that require the lower semiconductor structure 210 to be contracted via a controlled predetermined temperature decrease. Thus, in such a scenario, due to the existing misalignment, the lower alignment markers 212a, 212b may be located outside the width of the upper alignment markers 208a, 208b.

It may also be appreciated, among other things, that the microscope pairs 244, 246 have independent optical axes that do not require being aligned with respect to each other or another pair of opposing microscope axes. The optical axes of the each of the microscopes 244, 246 are substantially perpendicular to the surface of the semiconductor structures 207, 210.

Further, in some embodiments, the IR windows 242a, 242b within the lower bonding chuck 226 may alternatively be provided in the upper bonding chuck 224 on the basis of the microscopes 244, 246 imaging the alignment markers from the top rather than from the bottom. In other embodiments, both the upper and lower bonding chucks may have IR windows opposing each other and targeting the same set of alignment marks, or alternatively, not opposing each other and targeting different sets of alignment marks on the substrates to be bonded. In such an embodiment, the microscopes may image the alignment markers from either the top or the bottom. Since the microscopes receive and detect IR light, the region (alignment marker regions) of the semiconductor structures being imaged should be transparent to IR radiation. Thus, for example, if the silicon in these regions is heavily doped, or metallic interconnect structures have been fabricated within these regions, the IR radiation may be blocked. For this reason, the placement of the alignment markers may require such considerations. For example, the alignment markers may be placed in the dicing streets of wafers or within the edges of the semiconductor structures being bonded and stacked.

Although the above exemplary embodiments describe and depict the force pin applying a force to the center region of the semiconductor structure, in some embodiments, the force pin may exert the mechanical bonding force to one edge of the semiconductor structure, whereby a bonding wave is initiated from one edge of the semiconductor structure to the other. Moreover, in addition to the oxide bonding described in relation to the above embodiments, the apparatus and methods described herein may also apply to, for example, metal-metal bonding, hybrid bonding, or other types of bonding techniques.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A bonding apparatus comprising:
a plurality of infrared microscopes that emit and receive infrared light for imaging,
a first bonding chuck that holds a first semiconductor structure;
a second bonding chuck that holds a second semiconductor structure, the second bonding chuck having a plurality of openings that are transparent to the received infrared light;
a force pin coupled to the first bonding chuck, wherein the force pin applies a predetermined force to the first semiconductor structure for bonding to the second semiconductor structure; and
a temperature controller coupled to the second bonding chuck, wherein the temperature controller applies a predetermined temperature to the second semiconductor structure,
wherein, prior to the bonding, the first and the second semiconductor structure are de-aligned with respect to each other using the plurality of infrared microscopes and the plurality of openings, the de-aligning being based on the predetermined force and the application of the predetermined temperature.

2. The apparatus of claim 1, wherein:
the first semiconductor structure comprises a first plurality of alignment markers; and
the second semiconductor structure comprises a second plurality of alignment markers,
wherein the second plurality of alignment markers are de-aligned with respect to the first plurality of alignment markers by imaging the first and the second alignment markers, by the plurality of infrared microscopes, through the first and the second plurality of openings.

3. The apparatus of claim 2, wherein the first semiconductor structure comprises a first plurality of regions that respectively include the first plurality of alignment markers, the first plurality of regions being substantially transparent to the generated infrared light.

4. The apparatus of claim 2, wherein the second semiconductor structure comprises a second plurality of regions that respectively include the second plurality of alignment markers, the second plurality of regions being substantially transparent to the generated infrared light.

5. The apparatus of claim 1, wherein the predetermined temperature comprises a temperature increase having a range of about 0 to 10 degrees Celsius relative to an ambient temperature corresponding to the second semiconductor structure when positioned in the second bonding chuck.

6. The apparatus of claim 1, wherein the predetermined temperature comprises a temperature decrease having a range of about 0 to 10 degrees Celsius relative to an ambient temperature corresponding to the second semiconductor structure when positioned in the second bonding chuck.

7. The apparatus of claim 1, wherein the predetermined temperature comprises a temperature increase having a range of about 1 to 2 degrees Celsius relative to an ambient temperature corresponding to the second semiconductor structure when positioned in the second bonding chuck.

8. The apparatus of claim 1, wherein the predetermined temperature comprises a temperature decrease having a range of about 1 to 2 degrees Celsius relative to an ambient temperature corresponding to the second semiconductor structure when positioned in the second bonding chuck.

9. The apparatus of claim 1, wherein the predetermined force to the first semiconductor structure for bonding to the second semiconductor structure comprises a force in the range of about 0.5 Newtons to about 10 Newtons.

10. The apparatus of claim 1, wherein:
the first semiconductor structure comprises one of a first wafer and a first die; and
the second semiconductor structure comprises one of a second wafer and a second die.

11. A method of bonding a first semiconductor structure located within a first bonding chuck to a second semiconductor structure located within a second bonding chuck, the method comprising:
positioning the first bonding chuck relative to the second bonding chuck such that a first and a second alignment marker associated with the first semiconductor structure are substantially facing a third and a fourth alignment marker associated with the second semiconductor structure;
de-aligning the third alignment marker with respect to the first alignment marker using a first infrared microscope, the first infrared microscope receiving infrared light from the first and third alignment marker via an opening in the second bonding chuck;
de-aligning the fourth alignment marker with respect to the second alignment marker by a second infrared microscope, the second infrared microscope receiving infrared light from the second and fourth alignment marker via an other opening in the second bonding chuck; and
bonding the first and the second semiconductor structure by mechanical compression of the first and the second semiconductor structure together using the first and the second bonding chuck,
wherein the de-aligning of the third and the fourth alignment marker is accomplished by applying a temperature to the first chuck.

12. The method of claim 11, wherein the bonding comprises applying a predetermined force to the first chuck holding the first semiconductor structure.

13. The method of claim 12, wherein the applied predetermined force comprises a force of about 0.5 Newtons to about 10 Newtons.

14. The method of claim 11, wherein the applied temperature comprises providing a temperature increase in the range of about 0 to 10 degrees Celsius, the temperature increase physically expanding the second semiconductor structure.

15. The method of claim 11, wherein the applied temperature comprises providing a temperature decrease in the range of about 0 to 10 degrees Celsius, the temperature decrease physically contracting the second semiconductor structure.

16. The method of claim 11, wherein the de-aligning of the third and the fourth alignment marker is based on the mechanical compression.

17. The method of claim 16, wherein the de-aligning of the third and the fourth alignment marker is further based on alignment errors between the first and the second alignments markers, and the third and the fourth alignments markers caused by semiconductor structure distortion.

18. The apparatus of claim 11, wherein:
the first semiconductor structure comprises one of a first wafer and a first die; and
the second semiconductor structure comprises one of a second wafer and a second die.

19. A bonding chuck apparatus comprising:
a first bonding chuck that holds a first semiconductor structure;
a second bonding chuck that holds a second semiconductor structure, the second bonding chuck having a plurality of openings that are transparent to infrared light associated with a plurality of infrared microscopes, wherein the plurality of openings facilitate de-aligning the first and the second semiconductor structures using the plurality of infrared microscopes;
a force pin coupled to the first bonding chuck, wherein the force pin applies a predetermined force to the first semiconductor structure for bonding to the second semiconductor structure; and
a temperature controller coupled to the second bonding chuck, wherein the temperature controller applies a predetermined temperature to the second semiconductor structure for causing the de-aligning prior to the bonding,
wherein, upon bonding of the first semiconductor structure to the second semiconductor structure by the force pin, the first and the second semiconductor structure are realigned with respect to each other based on the application of the predetermined temperature prior to the bonding.

20. The apparatus of claim 19, wherein:
the first semiconductor structure comprises one of a first wafer and a first die; and
the second semiconductor structure comprises one of a second wafer and a second die.
